(19) United States
(12) Patent Application Publication
(10) Pub. No.: US 2025/0169333 A1
(43) Pub. Date: May 22, 2025

(54) DISPLAY DEVICE

(71) Applicant: LG Display Co., Ltd., Seoul (KR)

(72) Inventor: Hwangun SEO, Paju-si (KR)

(21) Appl. No.: 18/784,363

(22) Filed: Jul. 25, 2024

(30) Foreign Application Priority Data
Nov. 16, 2023 (KR) 10-2023-0159141

(51) Int. Cl. H10K 59/80

(52) U.S. Cl. CPC H10K 59/873; H10K 59/879

(57) ABSTRACT

A display device including a plurality of pixels according to one embodiment includes a circuit element layer including a circuit element, an organic light emitting element disposed on the circuit element layer, a cover member disposed on the organic light emitting element, and a coupling member between the organic light emitting device layer and the cover member. The cover member includes an indent pattern indented upward.

### CROSS REFERENCE TO RELATED APPLICATION

The present application claims priority to Korean Patent Application No. 10-2023-0159141, filed Nov. 16, 2023, the entire contents of which is incorporated herein for all purposes by this reference.

### BACKGROUND

### Technical Field

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

In particular, research for applying display panels and display devices to head-mounted electronic devices, glasses-type electronic devices, and the like to implement augmented reality images and virtual reality images.

### BRIEF SUMMARY

The present specification relates to a display device for implementing augmented reality images or virtual reality images and is directed to providing a display device including a lens for light efficiency.

The present specification is also directed to providing a display device with a simplified process by omitting a micro lens array (MLA) process of forming the lens.

The technical benefits of the present specification are not limited to the above-described benefits, and other technical benefits may be inferred from embodiments below.

To achieve the benefits, a display device including a plurality of pixels according to one embodiment includes a circuit element layer including a circuit element, an organic light emitting element disposed on the circuit element layer, a cover member disposed on the organic light emitting element, and a coupling member between the organic light emitting device layer and the cover member, wherein the cover member includes an indent pattern indented upward.

To achieve the benefits, a display device including a plurality of pixels according to another embodiment includes a circuit element layer including a circuit element, an insulating layer disposed on the circuit element layer, a reflective layer disposed in the insulating layer, an organic light emitting element disposed on the insulating layer and including an anode, an organic layer, and a cathode, a cover member disposed on the organic light emitting element, and a coupling member between the organic light emitting device layer and the cover member, wherein the cover member includes an indent pattern indented upward.

Detailed matters of other embodiments are included in a detailed description and accompanying drawings.

According to the embodiments, it is possible to provide the display device with the augmented reality images or the virtual reality images and increase luminous efficiency by including the micro lens in the convex shape.

In addition, it is possible to omit the micro lens array (MLA) process for forming the lens by forming the concave pattern in which the lens may be formed in the cover member, thereby providing the display device with the simplified process.

However, the effects obtainable from the present specification are not limited to the above-described effects, and other effects that are not mentioned will be able to be clearly understood by those skilled in the art to which the present specification pertains from the following description.

### BRIEF DESCRIPTION OF THE SEVERAL VIEWS OF THE DRAWINGS

FIG. 1 is a plan view of a display device according to one embodiment.

FIG. 2 is a cross-sectional view along line A-A′ in FIG. 1.

FIG. 3 is a schematic diagram showing a condensing function through a second portion of a coupling member of the display device according to FIG. 2.

FIG. 4 is a plan view showing the correspondence relationship between sub-pixels and the second portion of the display device according to one embodiment.

FIG. 5 is a process cross-sectional view showing a process of forming the second portion of the display device according to one embodiment.

FIG. 6 is a cross-sectional view of a display device according to another embodiment.

FIG. 7 is a plan view showing the correspondence relationship between the sub-pixels and the second portion of the display device according to FIG. 6.

FIG. 8 is a cross-sectional view of a display device according to still another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

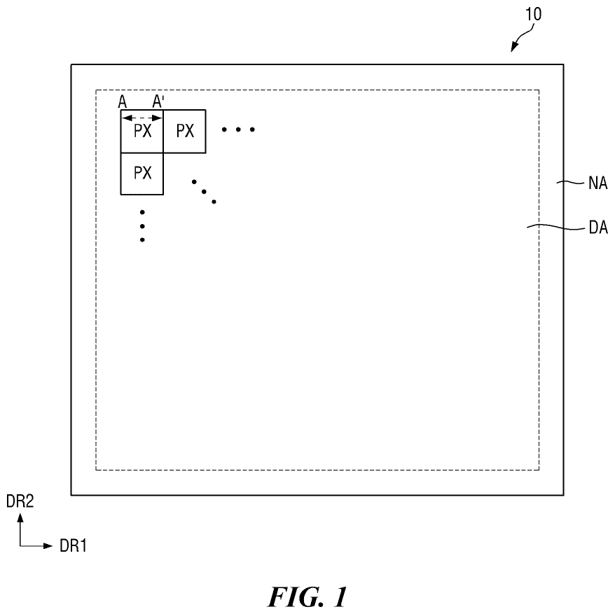

FIG. 1 is a plan view of a display device according to one embodiment.

Referring to FIG. 1, a display device 10 according to one embodiment may include a display panel DA and a non-display area NDA near the display area DA. The display area DA may include a plurality of pixels PX. The plurality of pixels PX may be, for example, arranged in a matrix manner in a first direction DR1 and a second direction DR2, but are not limited thereto. A planar shape of the pixel PX is shown as a quadrangle, but is not limited thereto and may be a triangular, circular, or elliptical shape, other polygonal shapes, or an irregular shape. Since no pixels PX are disposed in the non-display area NDA, images may not be displayed, but the present specification is not limited thereto.

The display device 10 according to one embodiment may be a display device for implementing augmented reality images or virtual reality images. However, the display device 10 may be applied not only to display devices for implementing the augmented reality images or the virtual reality images, but also to various applications.

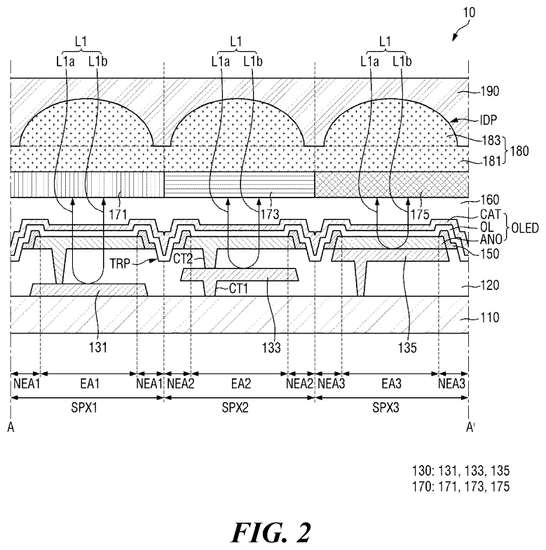

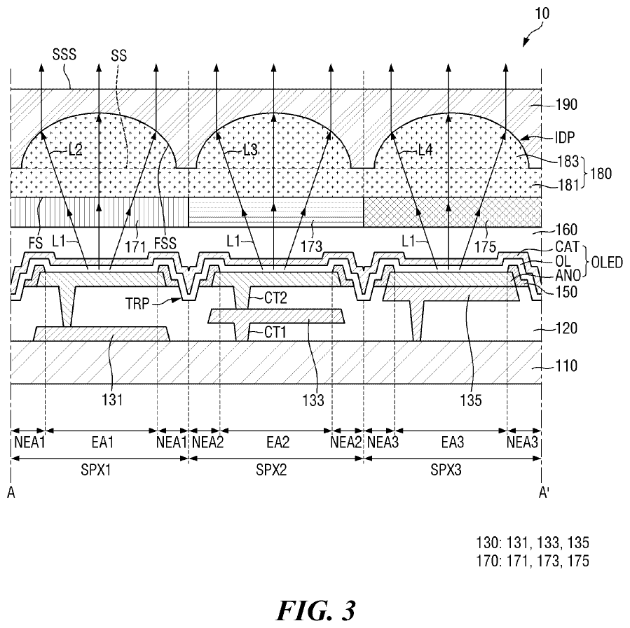

FIG. 2 is a cross-sectional view along line A-A′ in FIG. 1. FIG. 3 is a schematic diagram showing a condensing function through a second portion of a coupling member of the display device according to FIG. 2.

Referring to FIGS. 1 to 3, the pixel PX may include a plurality of sub-pixels SPX1, SPX2, and SPX3. For example, the pixel PX may include a first sub-pixel SPX1, a second sub-pixel SPX2, and a third sub-pixel SPX3. The first sub-pixel SPX1 may be a red pixel, the second sub-pixel SPX2 may be a green pixel, and the third sub-pixel SPX3 may be a blue pixel. In FIG. 2, the sub-pixels SPX1, SPX2, and SPX3 are shown as being disposed sequentially, but the arrangement order of the sub-pixels SPX1, SPX2, and SPX3 is not limited thereto.

Furthermore, in FIG. 2, the pixel PX is shown as including only three sub-pixels SPX1, SPX2, and SPX3, but is not limited thereto and may further include a white sub-pixel. Hereinafter, for convenience of description, a case where the pixel PX includes the three sub-pixels SPX1, SPX2, and SPX3 will be mainly described.

The sub-pixels SPX1, SPX2, and SPX3 may include emission areas EA1, EA2, and EA3 and non-emission areas NEA1, NEA2, and NEA3 near the emission areas EA1, EA2, and EA3, respectively. For example, the first sub-pixel SPX1 may include the first emission area EA1 and the first non-emission area NEA1 near the first emitting area EA1, the second sub-pixel SPX2 may include the second emission area EA2 and the second non-emission area NEA2 near the second emission area EA2, and the third sub-pixel SPX3 may include the third emission area EA3 and the third non-emission area NEA3 near the third emission area EA3. The emission areas EA1, EA2, and EA3 may be defined as areas exposed by a partition wall 150 of an anode ANO to be described below, and the non-emission areas NEA1, NEA2, and NEA3 may be defined as areas that are not the emission areas EA1, EA2, and EA3.

The display device 10 may include a circuit element layer 110 disposed across the sub-pixels SPX1, SPX2, and SPX3, an insulating layer 120 disposed on the circuit element layer 110, an organic light emitting diode (OLED) disposed on the insulating layer 120, the partition wall 150, an encapsulation layer 160 disposed on the OLED, a color filter layer 170 disposed on the encapsulation layer 160, a coupling member 180 disposed on the color filter 170, and a cover member 190 disposed on the coupling member 180.

The circuit element layer 110 may include circuit elements disposed in the sub-pixels SPX1, SPX2, and SPX3. Each of the circuit element may include a complementary metal-oxide semiconductor (CMOS) element, but is not limited thereto.

The insulating layer 120 may be disposed on the circuit element layer 110. The insulating layer 120 may include an insulating material. The insulating layer 120 may serve to insulate the circuit element layer 110 and the anode ANO. An example of the insulating material may include silicon oxide, but is not limited thereto.

The reflective layer 130 may be disposed in the insulating layer 120. The reflective layer 130 may include a first reflective layer 131 disposed in the first sub-pixel SPX1, a second reflective layer 133 disposed in the second sub-pixel SPX2, and a third reflective layer 135 disposed in the third sub-pixel SPX3. Locations of the reflective layers 131, 133, and 135 may be different in a thickness direction. For example, the first reflective layer 131 may be disposed directly above the circuit element layer 110, the second reflective layer 133 may be located at a central portion of the insulating layer 120, and the third reflective layer 135 may be disposed on an upper end portion the insulating layer 120, that is, directly under the anode electrode ANO. The location of each of the reflective layers 131, 133, and 135 may be designed to maximize the resonance effect between light emitted downward from an organic layer OL and light emitted upward from the organic layer OL. This will be described below.

The reflective layer 130 may include a reflective material. For example, the reflective layer 130 may include a reflective electrode. For example, the light transmittance of the reflective layer 130 may be 10% or less, but is not limited thereto.

The reflective layers 131, 133, and 135 may be electrically connected one-to-one to circuit elements of the circuit element layer 110 disposed thereunder. The second reflective layer 133 and the third reflective layer 135 may each be connected to the circuit element through a first contact hole CT1.

The insulating layer 120 may include trench portions TRP disposed in the non-emission areas NEA1, NEA2, and NEA3. The trench portion TRP may be formed by being trenched from an upper surface of the insulating layer 120 in the thickness direction.

The OLED may be disposed on the insulating layer 120. The OLED may include the anode ANO, the organic layer OL disposed on the anode ANO, and a cathode CAT disposed on the organic layer OL.

The anode ANO may be disposed in each of the sub-pixels SPX1, SPX2, and SPX3. The anode ANO may be disposed on the insulating layer 120.

The partition wall 150 may be disposed on the anode ANO. The partition wall 150 may expose a portion of an upper surface of the anode ANO. The partition wall 150 may define the emission areas EA1, EA2, and EA3 by exposing a central portion of the upper surface of the anode ANO. In the display area DA (see FIG. 1), areas in which the partition wall 150 is disposed may be defined as the non-emission areas NEA1, NEA2, and NEA3.

The organic layer OL may be disposed on the upper surface of the anode ANO and in an opening of the partition wall 150. The organic layer OL may include an organic light emitting layer, a hole injection/transport layer, and an electron injection/transport layer. The organic layer OL may be formed integrally across the entirety of the sub-pixels SPX1, SPX2, and SPX3, but may be physically cut off at the trench portion TRP.

The cathode CAT is disposed on the organic layer OL and the partition wall 150. The cathode CAT may be a common electrode disposed across a plurality of pixels PX in the display area DA. The organic layer OL, the anode ANO, and the cathode CAT may form the OLED.

In each of the sub-pixels SPX1, SPX2, and SPX3, the organic layer OL may emit light. The organic layer OL of each of the sub-pixels SPX1, SPX2, and SPX3 may emit first light L1. The first light L1 may be white light. The white light may include red light, green light, and blue light. The first light L1 may include a la light L1a traveling upward and a 1b light L1b traveling downward.

The light L1b emitted downward may transmit the anodes ANO and may be reflected from the reflective layers 131, 133, and 135 disposed thereunder. The light L1b reflected from the reflective layers 131, 133, and 135 may be constructively interfered with the light L1a emitted upward from the organic layer OL. In other words, locations of the reflective layers 131, 133, and 135 may be set in consideration of a condition in which the light L1b reflected from the reflective layers 131, 133, and 135 of the sub-pixels SPX1, SPX2, and SPX3 and the light L1a emitted upward from the organic layer OL are constructively interfered. More specifically, under the constructive interference condition, distances between the organic layer OL and the reflective layers 131, 133, and 135 disposed thereunder may be proportional to wavelength ranges of light L2, L3, and L4 emitted from the sub-pixels SPX1, SPX2, and SPX3. The second light L2 may be red light, the third light L3 may be green light, and the fourth light L4 may be blue light. Therefore, the first reflective layer 131, the second reflective layer 133, and the third reflective layer 135 may be located away from the organic layer OL in that order.

Meanwhile, since the light L1, L2, and L3 is partially reflected from the cathodes CAT, resonance may occur between the cathodes CAT and the reflective layers 131, 133, and 135. Even in this case, since a distance between lower surfaces of the cathodes CAT (or an upper surface of the organic layer OL) and the reflective layers 131, 133, and 135 disposed thereunder are set to the constructive interference condition, as resonance occurs, an intensity of the first light L1 transmitting the cathode CAT may be increased by being amplified. For example, in the first sub-pixel SPX1, the intensity of the red light of the first light L1 may be increased by being amplified, in the second sub-pixel SPX2, the intensity of the green light of the first light L1 may be increased by being amplified, and in the third sub-pixel SPX3, the intensity of the blue light of the first light L1 may be increased by being amplified.

The encapsulation layer 160 is disposed on the cathode CAT. The encapsulation layer 160 may cover the OLED. Although the encapsulation layer 160 is not shown, the encapsulation layer 160 may be a stacked film in which inorganic films and organic films are stacked alternately. For example, the encapsulation layer 160 may include a first inorganic encapsulation layer, an organic encapsulation layer, and a second inorganic encapsulation layer that are stacked sequentially. The first and second encapsulation inorganic layers may include an inorganic material. The encapsulation organic layer may include an organic material.

The color filter layer 170 may be disposed on the encapsulation layer 160. The color filter layer 170 may include a first color filter 171 disposed in the first sub-pixel SPX1, a second color filter 173 disposed in the second sub-pixel SPX2, and a third color filter 175 disposed in the third sub-pixel SPX3. The first color filter 171 may be a red color filter, the second color filter 173 may be a green color filter, and the third color filter 175 may be a blue color filter.

The first light L1 that reaches the color filter layer 170 may be filtered while transmitting the color filters 171, 173, and 175 in the sub-pixels SPX1, SPX2, and SPX3, respectively, and the second light L2, the third light L3, and the fourth light L4 may be emitted from the sub-pixels SPX1, SPX2, and SPX3, respectively.

The cover member 190 may be disposed on the color filter layer 170. The cover member 190 may serve to protect the display device 10 at the top. The cover member 190 may include glass or plastic, but is not limited thereto. The cover member 190 may include at least one indent pattern IDP. The indent pattern IDP may be formed by being indented upward from a lower surface of the cover member 190.

The coupling member 180 may be disposed between the cover member 190 and the color filter layer 170. The coupling member 180 may include an acrylic-based, epoxy-based, or silicon-based adhesive material, but is not limited thereto. The coupling member 180 may include a first portion 181 and a second portion 183 directly connected to the first portion 181. The first portion 181 and the second portion 183 may include the same material. However, the first portion 181 of the coupling member 180 is disposed at a different manufacturing stage from the second portion 183 of the coupling member 180 and therefore, the first portion 181 and the second portion 183 are distinct and separate structure from each other. The first portion 181 may be in direct contact with an upper surface of the color filter layer 170. The second portion 183 may be formed to protrude upward from the first portion 183. The second portion 183 may include a convex pattern. The second portion 183 may fill the indent pattern IDP of the cover member 190. The first portion 181 may be in direct contact with a portion of the cover member 190, in which the indent pattern IDP is not formed, and the color filter layer 170, and the second portion 183 may be in direct contact with the indent pattern IDP of the cover member 190.

The second portion 183 may serve as a lens. For example, the second portion 183 may include a micro lens and serve to condense the light L2, L3, and L4 provided from the bottom. That is, as shown in FIGS. 2 and 3, the display device may have a plurality of lenses 183. Each lens of the plurality includes the second portion 183 of the coupling member 180. In some embodiments, a refractive index of the second portion 183 is greater than a refractive index of the cover member 190. The combination of the shape of the cover member 190 and the differences in the refractive index of the second portion 183 and the cover member 190 forms the lens.

The light L2, L3, and L4 passing through the color filter layer 170 may be condensed in the second portion 183 and may travel forward.

A refractive index of the second portion 183 may be greater than that of the cover member 190. For example, the refractive index of the second portion 183 may be greater than 1.5 and smaller than or equal to 1.7, and the refractive index of the cover member 190 may be in the range of 1.4 to 1.5. Since the refractive index of the second portion 183 is greater than that of the cover member 190, the light L2, L3, and L4 passing through the color filter layer 170 may each be condensed in the second portion 183 and may travel forward.

In one embodiment, since the second portion 183 is included in the coupling member 180 and is made of the material of the coupling member 180, the strength of the second portion 183 may be lower than the strength of the cover member 190.

According to one embodiment, the cover member 190 may include at least one indent pattern IDP formed by being indented upward from the lower surface of the cover member 190, and the conventional MLA process for forming the micro lens may be omitted by forming the second portion 183 having the convex pattern through the indent pattern IDP of the cover member 190. Therefore, there is an advantage in that it is possible to simplify the process of the display device 10 including the micro lens.

As illustrated in FIG. 3, the first portion 181 of the coupling member 180 has a first surface FS and a second surface SS opposite the first surface FS. The first surface FS is between the second surface SS and the organic light emitting element OLED. The second portion 183 of the coupling member 180 is distinct and separate from the first portion 181 of the coupling member 180. The second portion 183 of the coupling member 180 is on and contacting the second surface SS of the first portion 181 of the coupling member 180.

As shown in FIGS. 2 and 3, the second portion 183 of the coupling member 180 protrudes in a direction opposite to the second surface SS of the first portion 181 and forms a shape of each lens.

In some embodiments, the cover member 190 has a first surface FSS and a second surface SSS opposite the first surface FSS. The first surface FSS of the cover member 190 has a shape corresponding to a shape of the second portion 183 of the coupling member 180 protruding in the direction opposite to the second surface SS of the first portion 181 of the coupling member 180. According to FIGS. 2 and 3, the second portion 183 may be seen as protruding upward extending into the cover member 190.

In some embodiments, the second surface SSS of the cover member 190 is planar. Further, the first surface FS of the first portion 181 and the second surface SS of the first portion 181 are planar. However, the present disclosure is not limited thereto.

In some embodiments, the cover member 190 is on and directly contacts the first 181 and second portions 183 of the coupling member 180.

In FIGS. 2 and 3, the insulating layer 120 is on the transistor (e.g., transistor may be located in the circuit element layer 110). The reflective layer (e.g., a first reflective layer 131, a second reflective layer 133, and a third reflective layer 135) is disposed within the insulating layer 120. The reflective layer is electrically connected to the anode ANO of the organic light emitting element. OLED.

The reflective layer may be disposed at a different location within the insulating layer 120 for at least one sub-pixel of the plurality of sub-pixels. For example, the first reflective layer 131 disposed in the first sub-pixel SPX1 is located closer to the circuit element layer 110 than the second reflective layer 133 disposed in the second sub-pixel SPX2 and the third reflective layer 135 disposed in the third sub-pixel SPX3. The third reflective layer 135 disposed in the third sub-pixel SPX3, on the other hand, may be located the farthest from the circuit element layer 110 than the second reflective layer 133 disposed in the second sub-pixel SPX2 and the first reflective layer 131 disposed in the first sub-pixel SPX1. In some embodiments, the third reflective layer 135 may be in direct contact with the anode electrode ANO of the OLED. In this case, a contact hole may not be present due to the third reflective layer 135 being directly and electrically connected to the anode electrode ANO of the OLED.

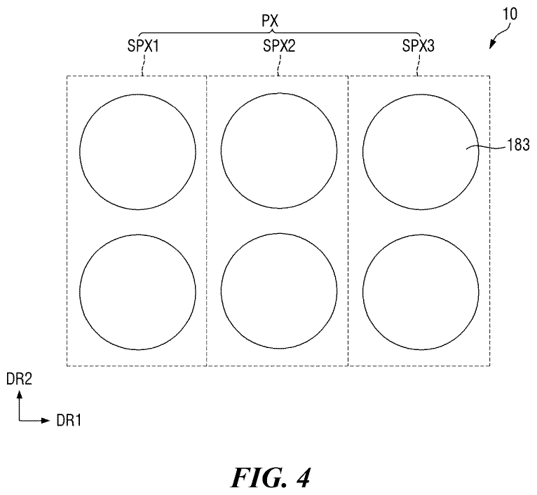

FIG. 4 is a plan view showing the correspondence relationship between sub-pixels and the second portion of the display device according to one embodiment.

Referring to FIG. 4, a plurality of second portions 183 may be disposed in each of the sub-pixel SPX1, SPX2, and SPX3. For example, two second portions 183 may correspond to each of the sub-pixels SPX1, SPX2, and SPX3. In each of the sub-pixels SPX1, SPX2, and SPX3, the second portions 183 may be disposed to be spaced apart from each other in the second direction DR2.

Unlike shown, the second portions 183 disposed in each of the sub-pixels SPX1, SPX2, and SPX3 may be physically connected in the second direction DR2. In some embodiments, the number of second portions 183 disposed in each of the sub-pixels SPX1, SPX2, and SPX3 may be three or more or one in the second direction DR2. Therefore, the number of indent patterns IDP corresponding to the second portion 183 may also be three or more or one in each of the sub-pixels SPX1, SPX2, and SPX3.

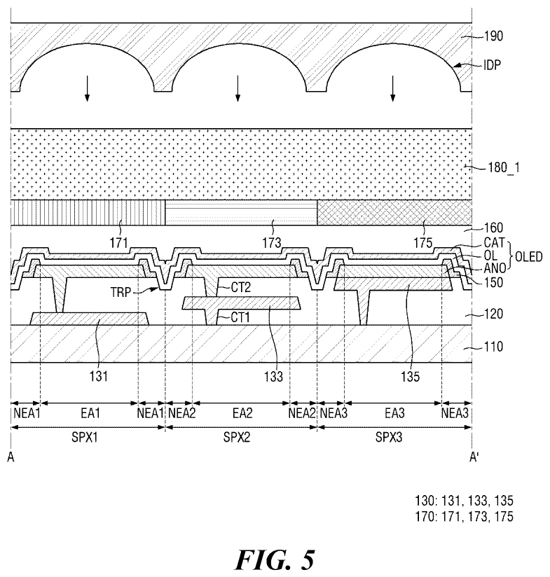

FIG. 5 is a process cross-sectional view showing a process of forming the second portion of the display device according to one embodiment.

Referring to FIGS. 1 to 5, a coupling member layer 180_1 is formed on the color filter layer 170. The coupling member layer 180_1 may include an acrylic-based, epoxy-based, or silicon-based adhesive material, but is not limited thereto. A refractive index of the coupling member layer 1801 may be greater than 1.5 and smaller than or equal to 1.7. A strength of the coupling member layer 1801 may be lower than that of the cover member 190.

Subsequently, the cover member 190 may move down toward the coupling member layer 180_1. The cover member 190 may serve to protect the display device 10 at the top. The cover member 190 may include glass or plastic, but is not limited thereto. The cover member 190 may include at least one indent pattern IDP. The indent pattern IDP may be formed by being indented upward from a lower surface of the cover member 190.

When the cover member 190 moves down toward the coupling member layer 180_1, the coupling member layer 180_1 is in direct contact with the lower surface of the cover member 190, fills the indent pattern IDP of the cover member 190, and is in direct contact with an inner surface of the indent pattern IDP. Through such a process, the first portions 181 and the second portions 183 of FIGS. 2 and 3 are formed.

According to one embodiment, the cover member 190 may include at least one indent pattern IDP formed by being indented upward from the lower surface of the cover member 190, and the conventional MLA process for forming the micro lens may be omitted by forming the second portion 183 having the convex pattern through the indent pattern IDP of the cover member 190. Therefore, there is an advantage in that it is possible to simplify the process of the display device 10 including the micro lens.

Hereinafter, another embodiment of the display device will be described.

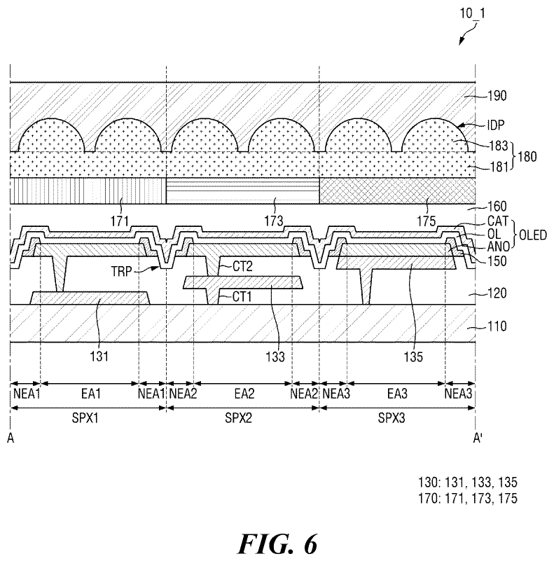

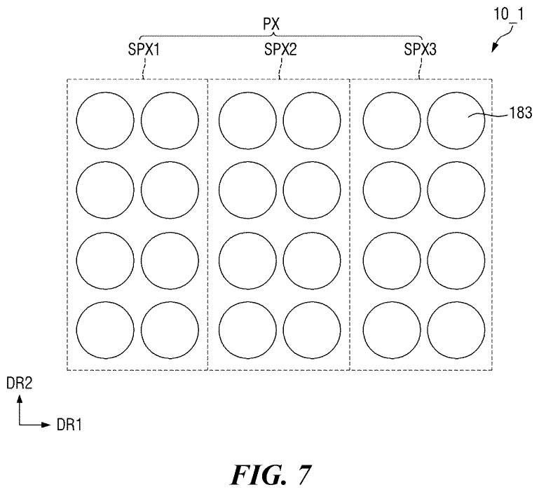

FIG. 6 is a cross-sectional view of a display device according to another embodiment. FIG. 7 is a plan view showing the correspondence relationship between the sub-pixels and the second portion of the display device according to FIG. 6.

Referring to FIGS. 6 and 7, a display device 10_1 according to the present embodiment differs from the display device 10 according to FIGS. 2 and 4 in that it has a plurality of indent patterns IDP in each of the sub-pixels SPX1, SPX2, and SPX3.

More specifically, as shown in FIG. 6, two indent patterns IDP may be present in each of the sub-pixels SPX1, SPX2, and SPX3 in a cross-sectional direction. Therefore, two second portions 183 corresponding to the indent pattern IDP may be present in each of the sub-pixels SPX1, SPX2, and SPX3 in the cross-sectional direction. Two indent patterns IDP or two second portions 183 may correspond to each of the sub-pixels SPX1, SPX2, and SPX3 in the cross-sectional direction. As shown in FIG. 7, two second portions 183 may be disposed in the first direction DR1 and four second portions 183 may be disposed in the second direction DR2 in each of the sub-pixels SPX1, SPX2, and SPX3. In addition, two indent patterns IDP corresponding to the second portion 183 may be disposed in the first direction DR1 and four indent patterns IDP may be disposed in the second direction DR2 in each of the sub-pixels SPX1, SPX2, and SPX3. However, the present specification is not limited thereto, and the number of second portions 183 or indent patterns IDP may be three or more in the first direction DR1, one to three or five or more in the second direction DR2 in each of the sub-pixels SPX1, SPX2, and SPX3.

In the case of the display device 10_1 shown in FIGS. 6 and 7, there is an advantage in that it is possible to more precisely condense the light L2, L3, and L4 provided from the color filter 170 by arranging two or more second portions 183 or indent patterns IDP in the first direction DR1 in each of the sub-pixels SPX1, SPX2, and SPX3.

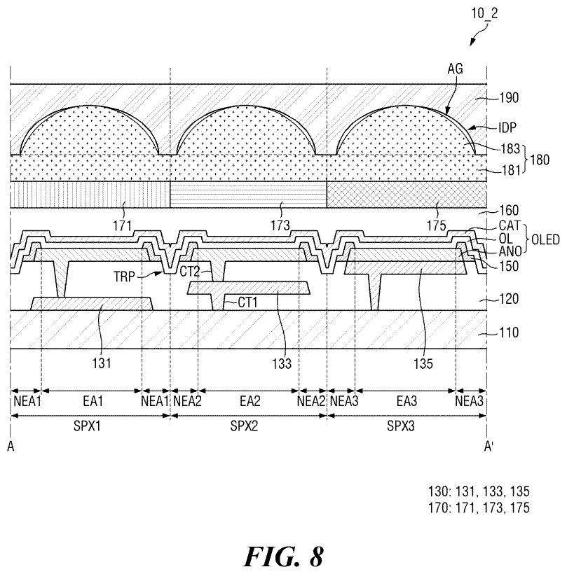

FIG. 8 is a cross-sectional view of a display device according to still another embodiment.

Referring to FIG. 8, a display device 10_2 according to the present embodiment differs from the display device 10 according to FIG. 2 in that an air gap AG may be formed between the second portion 183 and the inner surface of the indent pattern IDP of the cover member 190.

As described above with reference to FIG. 5, when the cover member 190 moves downward toward the coupling member layer 180_1, the coupling member layer 180_1 is in direct contact with the lower surface of the cover member 190, fills the indent pattern IDP of the cover member 190, and is in direct contact with the inner surface of the indent pattern IDP. Through such a process, the first portions 181 and the second portions183 of FIGS. 2 and 3 are formed.

However, during the manufacturing process according to FIG. 5, the coupling member layer 1801 may not fully fill the indent pattern IDP, and some air gaps AG may occur. The air gap AG may be disposed between the second portion 183 and the inner surface of the indent pattern IDP. That is, an air gap AG is present between the cover member 190 and the second portion 183 of the coupling member 180. A refractive index of the air gap AG may be about 1, and a difference in refractive index between the air gap AG and the second portion 183 may be greater than a difference in refractive index between the cover member 190 and the second portion 183. In an area in which the air gap AG occurs, there is an advantage in that the degree of refraction from the second portion 183 to the air gap AG is greater, thereby enhancing the light collection effect.

In some embodiments, a display device including a plurality of pixels includes a circuit element layer including a circuit element, an organic light emitting diode disposed on the circuit element layer, a cover member disposed on the organic light emitting diode, and a coupling member between the organic light emitting diode and the cover member, in which the cover member includes an indent pattern indented upward, and the coupling member includes a first portion between the organic light emitting diode and the cover member, and a second portion between the first portion and the cover member.

The display device may further include a color filter layer between the organic light emitting diode and the coupling member.

The coupling member may be disposed between the color filter layer and the cover member.

The first portion and the second portion may be directly connected.

The first portion and the second portion may include the same material.

A refractive index of the second portion may be greater than that of the cover member.

The refractive index of the cover member may be in the range of 1.4 to 1.5, and the refractive index of the second portion may be greater than 1.5 and 1.7 or less.

A strength of the second portion may be lower than that of the cover member.

The second portion may fill the indent pattern.

The second portion may serve as a micro lens.

The pixel may include a plurality of sub-pixels, and the second portions may correspond one to one to the sub-pixels in a cross-sectional direction.

The pixel may include a plurality of sub-pixels, and a plurality of second portions may correspond to one sub-pixel in a cross-sectional direction.

In some embodiments, a display device including a plurality of pixels includes a circuit element layer including a circuit element, an insulating layer disposed on the circuit element layer, a reflective layer disposed in the insulating layer, an organic light emitting diode disposed on the insulating layer and including an anode, an organic layer, and a cathode, a cover member disposed on the organic light emitting diode, and a coupling member between the organic light emitting diode and the cover member, in which the cover member includes an indent pattern indented upward, and the coupling member includes a first portion between the organic light emitting diode and the cover member, and a second portion between the first portion and the cover member.

The display device may further include a color filter layer between the organic light emitting diode and the coupling member, and the coupling member may be disposed between the color filter layer and the cover member.

A refractive index of the second portion may be greater than that of the cover member.

A strength of the second portion may be lower than that of the cover member.

The second portion may fill the indent pattern, and the second portion may serve as a micro lens.

The pixel may include a plurality of sub-pixels, and the second portions may correspond one-to-one to the sub-pixels or correspond to one sub-pixel.

Although the embodiments have been described above with reference to the accompanying drawings, those skilled in the art to which the present specification pertains will be able to understand that the above-described technical configuration can be carried out in other specific forms without changing the technical spirit or essential features thereof. Therefore, it should be understood that the above-described embodiments are illustrative and not restrictive in all respects. In addition, the scope of the present specification is described by the claims to be described below rather than the detailed description. In addition, the meaning and scope of the claims and all changed or modified forms derived from the equivalent concept should be construed as being included in the scope of the present specification.

### DESCRIPTION OF REFERENCE NUMERALS

10: display device
110: circuit element layer
120: insulating layer
130: reflective layer
OLED: organic light emitting element
150: partition wall
180: coupling member
181: first portion
183: second portion
IDP: indent pattern
190: cover member

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a plurality of pixels;
a circuit element layer including a circuit element;
an organic light emitting element disposed on the circuit element layer;
a cover member disposed on the organic light emitting element; and
a coupling member between the organic light emitting device layer and the cover member,
wherein the cover member includes an indent pattern indented upward, and
wherein the coupling member includes a first portion between the organic light emitting device layer and the cover member, and a second portion between the first portion and the cover member.

2. The display device of claim 1, further comprising a color filter layer between the organic light emitting diode and the coupling member.

3. The display device of claim 2, wherein the coupling member is disposed between the color filter layer and the cover member.

4. The display device of claim 1, wherein the first portion and the second portion are directly connected.

5. The display device of claim 1, wherein the first portion and the second portion include the same material.

6. The display device of claim 1, wherein a refractive index of the second portion is greater than a refractive index of the cover member.

7. The display device of claim 6, wherein the refractive index of the cover member is in the range of 1.4 to 1.5, and the refractive index of the second portion is greater than 1.5 and 1.7 or less.

8. The display device of claim 1, wherein a strength of the second portion is lower than a strength of the cover member.

9. The display device of claim 1, wherein the second portion fills the indent pattern.

10. The display device of claim 1, wherein the second portion serves as a micro lens.

11. The display device of claim 1, wherein the pixel includes a plurality of sub-pixels, and
wherein the second portion corresponds one-to-one to the sub-pixels in a cross-sectional direction.

12. The display device of claim 1, wherein the pixel includes a plurality of sub-pixels, and
wherein a plurality of second portions corresponds to one sub-pixel in a cross-sectional direction.

13. A display device comprising:
a plurality of pixels on a substrate;
an insulating layer disposed on the substrate;
a reflective layer disposed in the insulating layer;
an organic light emitting element disposed on the insulating layer and including an anode, an organic layer, and a cathode;
a cover member disposed on the organic light emitting element; and
a coupling member between the organic light emitting device layer and the cover member,
wherein the cover member includes an indent pattern indented in a first direction, and
wherein the coupling member includes a first portion between the organic light emitting device layer and the cover member, and a second portion between the first portion and the cover member.

14. The display device of claim 13, further comprising a color filter layer between the organic light emitting diode and the coupling member, wherein the coupling member is disposed between the color filter layer and the cover member.

15. The display device of claim 13, wherein a refractive index of the second portion is greater than that of the cover member.

16. The display device of claim 13, wherein a strength of the second portion is lower than that of the cover member.

17. The display device of claim 13, wherein the second portion fills the indent pattern, and the second portion serves as a micro lens.

18. The display device of claim 13, wherein the pixel includes a plurality of sub-pixels, and
wherein the second portions correspond one-to-one to the sub-pixels, or correspond to one sub-pixel.

19. A display device comprising:
a plurality of sub-pixels, each sub-pixel of the plurality including:
an organic light emitting element including an anode, an organic layer, and a cathode; and
a transistor electrically connected to the organic light emitting element;
a cover member on the organic light emitting element;
a coupling member between the organic light emitting device layer and the cover member, the coupling member having a first portion and a second portion, the second portion on the first portion; and
a plurality of lenses, each lens of the plurality including the second portion of the coupling member, a refractive index of the second portion being greater than a refractive index of the cover member.

20. The display device of claim 19, wherein the first portion of the coupling member has a first surface and a second surface opposite the first surface, the first surface being between the second surface and the organic light emitting element.

21. The display device of claim 20, wherein the second portion of the coupling member is distinct and separate from the first portion of the coupling member,
wherein the second portion of the coupling member is on and contacting the second surface of the first portion of the coupling member, and
wherein the second portion of the coupling member protrudes in a direction opposite to the second surface of the first portion and forms a shape of each lens of the plurality.

22. The display device of claim 21, wherein the cover member has a first surface and a second surface opposite the first surface, and
wherein the first surface of the cover member has a shape corresponding to a shape of the second portion of the coupling member protruding in the direction opposite to the second surface of the first portion of the coupling member.

23. The display device of claim 22, wherein the second surface of the cover member is planar, and
wherein the first surface of the first portion and the second surface of the first portion are planar.

24. The display device of claim 19, wherein the cover member directly contacts the first and second portions of the coupling member.

25. The display device of claim 19, further comprising:
an insulating layer on the transistor; and
a reflective layer within the insulating layer, the reflective layer electrically connected to the anode of the organic light emitting element.

26. The display device of claim 25, wherein the reflective layer is disposed at a different location within the insulating layer for at least one sub-pixel of the plurality of sub-pixels.

27. The display device of claim 19, further comprising:
an air gap between the cover member and the second portion of the coupling member.

28. The display device of claim 27, wherein a difference in refractive index between the air gap and the second portion of the coupling member is greater than a difference in refractive index between the cover member and the second portion of the coupling member.
